(19) United States
(12) Patent Application Publication
(10) Pub. No.: US 2008/0111589 A1
(43) Pub. Date: May 15, 2008

(54) SYSTEM FOR ADJUSTING DRIVING CAPABILITY OF OUTPUT STAGE

(75) Inventors: Shian-Sung Shiu, Taipei City (TW); Kuo-Wei Peng, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: BEYOND INNOVATION TECHNOLOGY CO., LTD., Taipei City (TW)

(21) Appl. No.: 11/614,939

(22) Filed: Dec. 21, 2006

(30) Foreign Application Priority Data
Nov. 10, 2006 (TW) 95141630

(51) Int. Cl. H03K 3/00

(52) U.S. Cl. 327/109; 327/108

(57) ABSTRACT

A driving adjustment circuit that increases the driving capability of amplifier by adding a driving current directly to an output stage of the amplifier is provided. The driving adjustment circuit adjusts the driving capability according to an external load. Thus, the present invention not only solves the problem of insufficient driving capability of a digital-to-analog converter, but also effectively reduces unnecessary high power consumption and improves the stability of the system by adjusting the driving capability of the amplifier according to the external load.

### CROSS-REFERENCE TO RELATED APPLICATION

This application claims the priority benefit of Taiwan application serial no. 95141630, filed on Nov. 10, 2006. All disclosure of the Taiwan application is incorporated herein by reference.

### BACKGROUND OF THE INVENTION

1. Field of the Invention

The present invention relates to a system for adjusting a driving capability. More particularly, the present invention relates to a system for adjusting the driving capability of an output stage and an application thereof.

2. Description of Related Art

In recent years, with the development of liquid crystal display s (LCDs), consumers have increasingly higher requirements for LCDs, including large-size monitors, notebook computers, or LCD TVs, and small-size high-resolution color-screen mobile phones, personal digital assistants (PDAs), and global positioning system (GPS) devices. The consumers not only require powerful functions of the products, but also require stable systems and low power consumption. According to the conventional art, in order to ensure the normal operation of various elements in a circuit, an over-high driving capability is adopted. However, the over-high driving capability leads to unnecessary power consumption of a system, and increases the system temperature which, if too high, will cause instability of the system. Therefore, if the excessively high driving capability is not used, the power consumption can be lowered, and the stability of the system will naturally be improved.

FIG. 1 is a schematic circuit diagram of a conventional pixel driving circuit. Referring to FIG. 1, in the conventional art, a pixel driving circuit 100 includes a digital-to-analog conversion unit 120 and an operational amplifier unit 130. The digital-to-analog conversion unit 120 is coupled to the operational amplifier unit 130. The digital-to-analog conversion unit 120 includes digital-to-analog converters 121, 122 which convert digital signals to analog signals and output the analog signals to operational converters 131, 132. The operational amplifiers 131, 132 in the operational amplifier unit 130 enhance the driving capability of the pixel driving circuit 100, so as to drive sub-pixel units 111, 112 of a panel 110.

It should be noted that when the resolution, size, and manufacturing process of the panel 110 is different; the driving capability required by the panel 110 will be different. However, in the conventional driving process, the driving capability of the operational amplifiers 131, 132 is fixed and cannot be changed. Therefore, regardless of whether the load on the panel 110 is high or low, the operational amplifiers 131, 132 cannot adjust the driving capability according to the load, but can output the same driving capability only. According to the conventional art, if the size of the panel is large, and the required driving current is high, the driving capability of the operational amplifiers 131, 132 will be insufficient to drive the sub-pixel units 111, 112 of the panel 110. Therefore, the contrast of images displayed by the panel 110 is insufficient, thus adversely influencing the display quality. In order to drive the sub-pixel units 111, 112 of the panel 110 successfully, the operational amplifiers 131, 132 usually have over-high driving capability according to the conventional art. This method will lead to unnecessary power consumption. The extra and unnecessary power consumption will cause the increase of the system temperature, which may in turn render system instable.

Therefore, panel manufacturers have to find solutions to overcome the above problems.

### SUMMARY OF THE INVENTION

The present invention is directed to provide a driving adjustment circuit capable of varying an output driving capability according to an external load.

The present invention is further directed to provide a pixel driving circuit capable of varying an output driving capability according to a load on a panel so that it can be applied to panels of different sizes.

The present invention is also directed to provide a display device capable of varying the driving capability according to a load on a display device to provide optimal driving capability, and thereby reduce the rising of temperature caused by unnecessarily higher power consumption and thereby improve the system stability.

As embodied and broadly described herein, a circuit comprising an output stage and a driving adjustment circuit is provided. The output stage comprises an output terminal. The driving adjustment circuit provides a driving current to the output terminal directly to adjust the driving capability of the output stage.

According to a preferred embodiment of the present invention, the driving adjustment circuit is suitable for adjusting the driving capability of an operational amplifier. The operational amplifier comprises an output stage coupled between a working voltage and a ground terminal, and the output stage has an output terminal. The driving adjustment circuit comprises a first current source unit and a second current source unit. The first current source unit is coupled between the working voltage and the output terminal. The second current source unit is coupled between the output terminal and the ground terminal. The driving adjustment circuit adjusts a driving current of the driving stage according to a magnitude of the current conducted by the first current source and the second current source.

According to a preferred embodiment of the present invention, the output stage comprises a first transistor and a second transistor. The first transistor is coupled between the working voltage and the output terminal, and a control terminal of the first transistor is coupled to a first bias. The second transistor is coupled between the output terminal and the ground terminal, and a control terminal of the second transistor is coupled to a second bias. The operational amplifier is an operational amplifier. The operational amplifier adjusts the first bias and the second bias according to an input signal, so as to adjust the driving current of the output stage.

As embodied and broadly described herein, a digital-to-analog conversion device comprising a digital-to-analog converter, an operational amplifier, and a driving adjustment circuit is provided. The digital-to-analog converter receives a digital signal to generate an analog signal. The operational amplifier receives the analog signal to drive the output. The driving adjustment circuit provides a driving current to the output terminal of the operational amplifier directly to adjust the driving capability of the operational amplifier.

The digital-to-analog conversion device according to a preferred embodiment of the present invention comprises a digital-to-analog converter, an operational amplifier, and a driving adjustment circuit. The digital-to-analog converter generates an analog signal according to a digital signal. The operational amplifier has an output stage. The operational amplifier is coupled to the digital-to-analog converter, and outputs a driving voltage from the output stage according to the analog signal. The output stage is coupled between the working voltage and the ground terminal. The driving adjustment circuit is coupled to the output stage of the operational amplifier, so as to adjust the driving current of the output stage.

According to a preferred embodiment of the present invention, the output stage comprises a first transistor and a second transistor. The first transistor is coupled between the working voltage and the output terminal, and a control terminal of the first transistor is coupled to a first bias. The second transistor is coupled between the output terminal and the ground terminal, and a control terminal of the second transistor is coupled to a second bias. The operational amplifier adjusts the first bias and the second bias according to an input signal, so as to adjust the driving current of the output stage.

As embodied and broadly described herein, a display device comprising a panel, an output stage, and a driving adjustment circuit is provided. The panel has a plurality of sub-pixel units. The output stage is used to receive an image signal and output the image signal from an output terminal. The driving adjustment circuit provides a driving current to the output terminal directly, so as to adjust the capability of an input stage to drive the panel.

The display device according to a preferred embodiment of the present invention comprises a panel and a control circuit. The panel has a plurality of sub-pixel units. A plurality of pixel driving circuits is used to sequentially drive the sub-pixel units. The control circuit is coupled to the pixel driving circuits, so as to adjust the driving capability of the pixel driving circuits. Each of the pixel driving circuits has a driving adjustment circuit, and the control circuit adjusts driving currents of the pixel driving circuits with the corresponding driving adjustment circuits.

According to a display device of the present invention, each of the pixel driving circuits comprises an operational amplifier having an output stage to output a driving voltage from the output stage according to an analog signal. The output stage is coupled between a working voltage and a ground terminal. The driving adjustment circuit is coupled to the output stage of the operational amplifier, so as to adjust a driving current of the output stage.

The display device according to a preferred embodiment of the present invention comprises a panel, a plurality of pixel driving circuits, and control circuits. The panel has a plurality of sub-pixel units. The pixel driving circuits are used to drive the sub-pixel units sequentially. The control circuits are coupled to the pixel driving circuits. The pixel driving circuits respectively comprises a first current source unit and a second current source unit, and the control circuits adjust driving currents of the pixel driving circuits according to a magnitude of the current conducted by the first current source unit and the second current source unit.

In the display device according to a display device of the present invention, each of the pixel driving circuits comprises an operational amplifier having an output stage to output a driving voltage from the output stage according to an analog signal. The output stage is coupled between a working voltage and a ground terminal. A first current source unit is coupled between the working voltage and an output terminal, and a second current source is coupled between the output terminal and the ground terminal.

In view of the above, the present invention uses a driving adjustment circuit to improve the driving capability of an amplifier by increasing a current of an output stage of the amplifier. The driving adjustment circuit adjusts the driving capability according to an external load. Thus, the present invention not only solves the problem of insufficient driving capability of a digital-to-analog converter, but also effectively reduces unnecessary higher power consumption and improves the stability of the system by adjusting the driving capability of the amplifier according to the external load.

In order to make the aforementioned and other aspects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic circuit diagram of a conventional pixel driving circuit.

FIG. 2A is an architectural view of an operational amplifier capable of adjusting the driving capability according to a preferred embodiment of the present invention.

FIG. 2B is a circuit diagram of a unit gain circuit according to another embodiment of the present invention.

FIG. 2C is a circuit diagram of a driving adjustment circuit according to another embodiment of the present invention.

FIG. 2D is a circuit diagram of a driving adjustment circuit according to yet another embodiment of the present invention.

FIG. 3 is a circuit diagram of an operational amplifier capable of adjusting the driving capability according to a preferred embodiment of the present invention.

FIG. 4 is a schematic view of a pixel driving circuit of an amplifier capable of adjusting the driving capability according to a preferred embodiment of the present invention.

FIG. 5 is a schematic view of a display device with an operational amplifier capable of adjusting the driving capability according to a preferred embodiment of the present invention.

FIG. 6 is a schematic view of the control circuit applied in a display device capable of adjusting the driving capability according to a preferred embodiment of the present invention.

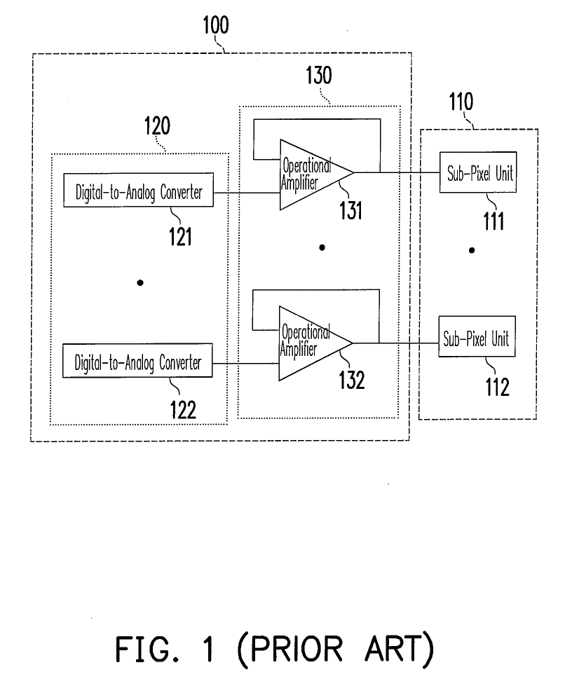

### DESCRIPTION OF EMBODIMENTS

In the embodiments below, when a device is described as being “connected” or “coupled” to another device, the device can be directly connected or coupled to another device, or other devices can be arranged therebetween.

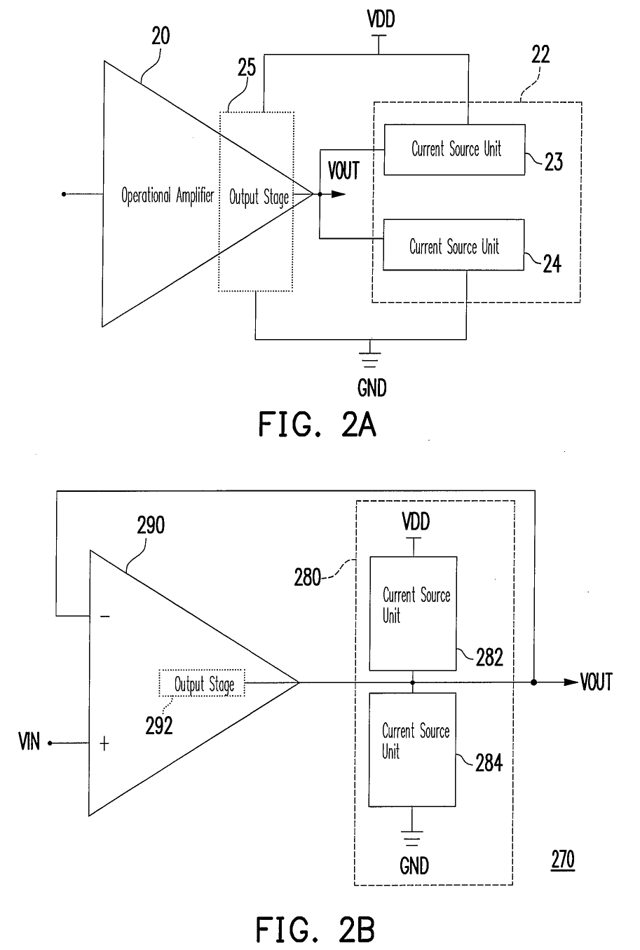

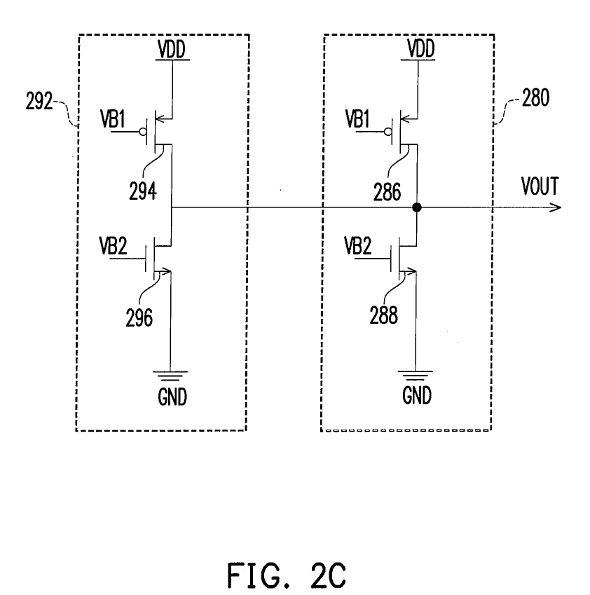

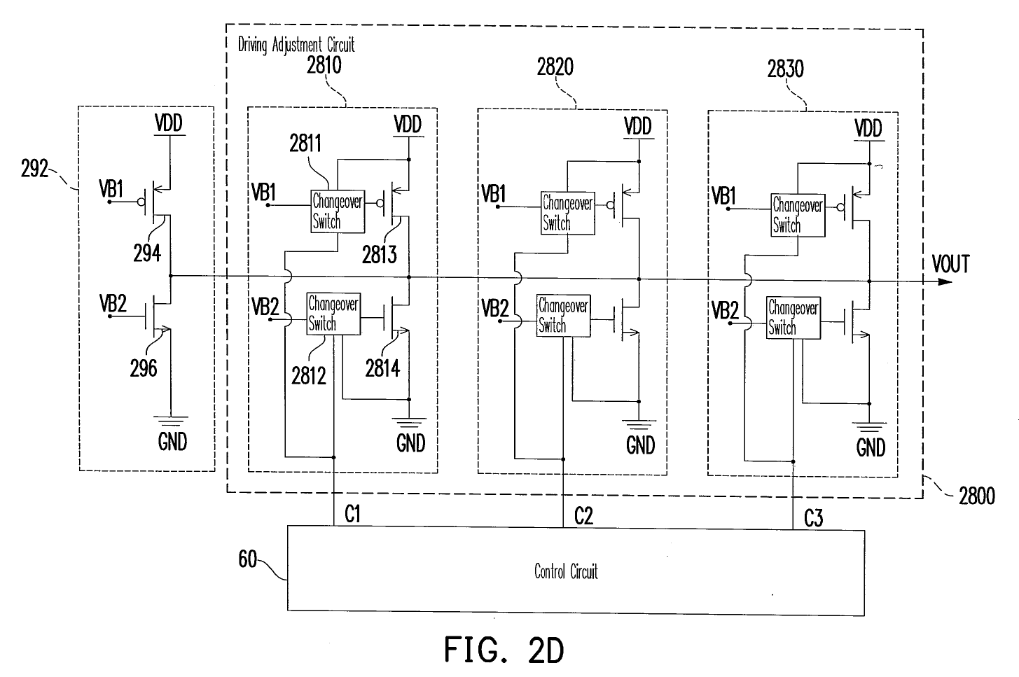

FIG. 2A is an architectural view of an operational amplifier capable of adjusting the driving capability according to a preferred embodiment of the present invention. Referring to FIG. 2A, a driving adjustment circuit 22 is coupled to an output terminal VOUT of an amplifier 20, so as to increase a driving current of an output stage 25 directly. The output stage 25 is an amplifying circuit. The operational amplifier 20 includes the output stage 25. The output stage 25 is coupled between a working voltage VDD and a ground terminal GND, and has the output terminal VOUT. The driving adjustment circuit 22 includes a current source unit 23, 24, so as to form a current source circuit. The current source unit 23 and the current source unit 24 are coupled to the output terminal VOUT of the operational amplifier 20 respectively. The operational amplifier 20 receives and amplifies an analog signal, and outputs a driving current from the output terminal of the output stage 25. The output driving capability of the operational amplifier 20 is fixed. However, in a different application, the load connected to the operational amplifier 20 varies according to different external applications. When the external load connected is low, an extra power is consumed. When the external load connected is high, the driving capability is insufficient. Therefore, the driving adjustment circuit 22 can further adjust the output driving capability of the operational amplifier 20 according to the load connected to the operational amplifier 20. Thus, the possibility of extra power consumption or insufficient driving capability in applications is reduced, and thereby to provide greater flexibility in system application.

In another embodiment of the present invention, the operational amplifier 20 can be an operational amplifier, as shown in FIG. 2B. FIG. 2B is a circuit diagram of a unit gain circuit according to another embodiment of the present invention. The unit gain circuit 270 includes an operational amplifier 290 and a driving adjustment circuit 280. The driving adjustment circuit 280 is coupled to an output terminal VOUT of the operational amplifier 290, so as to enhance the current driving capability of the operational amplifier 290. In this embodiment, a negative input terminal of the operational amplifier 290 is coupled to the output terminal VOUT, and a positive input terminal is coupled to an input signal VIN, so as to form the unit gain circuit 270. In another embodiment of the present invention, if the input signal VIN is a differential signal, the signal can be input from the negative input terminal and the positive input terminal of the operational amplifier 290. Those of ordinary skills in the art can easily deduce the application method and working principle according to the disclosure of the present invention, and therefore detailed description thereof will not be described herein.

The driving adjustment circuit 280 includes current source units 282, 284. The current source unit 282 is coupled between a working voltage VDD and the output terminal VOUT, and the current source unit 284 is coupled between the output terminal VOUT and the ground terminal GND. The current driving capability of the unit gain current 270 can be adjusted by adjusting the conducted current of the current source units 282, 284. In other words, when the current source units 282, 284 conduct the current, the driving current of the output stage 292 increases accordingly, and the driving capability is enhanced. In this embodiment, in order to enable the current source units 282, 284 to increase the driving current of the output stage 292 effectively without adversely influencing the normal operation of the operational amplifier 290, the current source units 282, 284 can be designed symmetrically according to the circuit architecture of the output stage 292, such that the current conducted by the current source units 282, 284 is a multiple of the driving current of the output stage 292. In other words, the circuit architecture of the current source units 282, 284 can be designed with reference to the output stage 292.

The unit gain circuit 270 of the embodiment of FIG. 2 can also be used a buffer of a source driver in a panel driving circuit, so as to enhance the capability of the source driver to drive pixels. When the load that the panel driving panel is required to drive varies, the driving capability of the source driver can be enhanced by merely changing the magnitude of the current conducted by the driving adjustment circuit 280.

Next, the design of one of the current source units 282, 284 of the embodiment of FIG. 2B will be further described below. FIG. 2C is a circuit diagram of a driving adjustment circuit according to another embodiment of the present invention. Referring to FIG. 2C, the output stage 292 is composed of a P-type metal oxide semiconductor (PMOS) transistor 294 and an N-type metal oxide semiconductor (NMOS) transistor 296 connected in series between the working voltage VDD and the ground terminal GND. The output stage 292 includes a PMOS transistor 294 and an NMOS transistor 296, and a common node of the PMOS transistor 294 and the NMOS transistor 296 is the output terminal VOUT. A gate of the PMOS transistor 294 is coupled to a working bias VB1, and a gate of the NMOS transistor 296 is coupled to a working bias VB2. The working biases VB1, VB2 are provided by an internal circuit of the operational amplifier 290. The driving adjustment circuit 280 has the similar circuit architecture as the output stage 292, which is composed of a PMOS transistor 286 and an NMOS transistor 288 connected in series between the working voltage VDD and the ground terminal GND.

In this embodiment, the driving capability of the output stage 292 can be adjusted by controlling gate voltages of the PMOS transistor 286 and the NMOS transistor 288. For example, a gate of the PMOS transistor 286 is coupled to the working bias VB1, and a gate of the NMOS transistor 288 is coupled to the working bias VB2. The working biases VB1, VB2 are also provided by the internal circuit of the operational amplifier 290. As the driving adjustment circuit 280 and the output stage 292 have the same structure, the driving current of the output stage 292 at the output terminal VOUT is doubled, which is equivalent to doubling the driving capability. Those of ordinary skills in the art can further expand the circuit architecture of the driving adjustment circuit 280 according to the circuit design similar to the output stage 292 as required, so as to increase the driving current, and the detailed description thereof will not be described herein.

FIG. 2D is a circuit diagram of a driving adjustment circuit according to another embodiment of the present invention. The driving adjustment circuit 2800 forms a serial circuit of multiple stages according to the output stage 292, such that the driving capability of the output stage 292 has more flexible adjusting capability, and the driving capability of the output stage 292 can be adjusted by a control circuit 60. The output stage 292 is the same as the embodiment of FIG. 2C, and will not be described herein again. It should be noted that a first-stage driving adjustment circuit 2810 of a driving adjustment circuit 2800 includes a PMOS transistor 2813 and an NMOS transistor 2814. The PMOS transistor 2813 and the NMOS transistor 2814 are connected in series between the working voltage VDD and the ground terminal GND. A gate of the PMOS transistor 2813 is coupled to a transfer switch 2811. The transfer switch 2811 switches the gate of the PMOS transistor 2813 according to a control signal C1 output from the control circuit 60, such that the gate of the PMOS transistor 2813 is coupled to the working bias VB1 or the working voltage VDD. When the control signal C1 is logic 0, the gate of the PMOS transistor 2813 is coupled to the working voltage VDD, and the PMOS transistor 2813 does not conduct a current. When the control signal C1 is logic 1, the gate of the PMOS transistor 2813 is coupled to the working bias VB1, and the PMOS transistor 2813 has the same conducted current as the PMOS transistor 294 because the channel width/channel length (W/L) of the PMOS transistor 2813 is the same as the W/L of the PMOS transistor 294.

A gate of the NMOS transistor 2814 is coupled to a transfer switch 2812. The transfer switch 2812 switches the gate of the NMOS transistor 2814 according to the control signal C1 output from the control circuit 60, such that the gate of the NMOS transistor 2814 is coupled to the working bias VB2 or the ground terminal GND. When the control signal C1 is logic 0, the gate of the NMOS transistor 2814 is coupled to the ground terminal GND, and the NMOS transistor 2814 does not conduct a current. When the control signal C1 is logic 1, the gate of the NMOS transistor 2814 is coupled to the working bias VB2, and the NMOS transistor 2814 has the same conducted current as the NMOS transistor 296 of the output stage 292. Therefore, when the control signal C1 is logic 1, the PMOS transistor 2813 and the NMOS transistor 2814 both conduct current, and the conducted current can enhance the driving capability of the output stage 292.

Those of ordinary skill in the art can easily understand the application and working principle of a second-stage driving adjustment circuit 2820 and a third-stage driving adjustment circuit 2830 having same components as the first-stage driving adjustment circuit 2810 in the driving adjustment circuit 2800 according to the disclosure of the present invention. Control signals C2 and C3 output from the control circuit 60 control the second-stage driving adjustment circuit 2820 and the third-stage driving adjustment circuit 2830 respectively, so as to adjust the driving capability of the output stage 292, and the details will not be described herein again. In addition, various PMOS transistors of the driving adjustment circuit 2800 can be regarded as a current source unit, and various NMOS transistors can be regarded as another current source unit.

The control circuit 60 has three output terminals, which output the control signal C1, the control signal C2, and the control signal C3 respectively. The control signal C1 is used to control whether to enable the PMOS transistor 2813 and the NMOS transistor 2814 of the first-stage driving adjustment circuit 2810. Similarly, the control signal C2 is used to control whether to enable the PMOS transistor and the NMOS transistor of the second-stage driving adjustment circuit 2820. The control signal C3 is used to control whether to enable the PMOS transistor and the NMOS transistor of the third-stage driving adjustment circuit 2830. The control circuit 60 is designed corresponding to the driving adjustment circuit 2800. That is, when the driving adjustment circuit 2800 includes the first-stage driving adjustment circuit 2810, the second-stage driving adjustment circuit 2820, and the third-stage driving adjustment circuit 2830, the control circuit 60 must output three control signals C1, C2, and C3 correspondingly. Similarly, when the driving adjustment circuit 2800 includes N stages of driving adjustment circuits (not shown), the control circuit 60 must output N control signals (not shown) respectively provided to N stages of driving adjustment circuits (not shown).

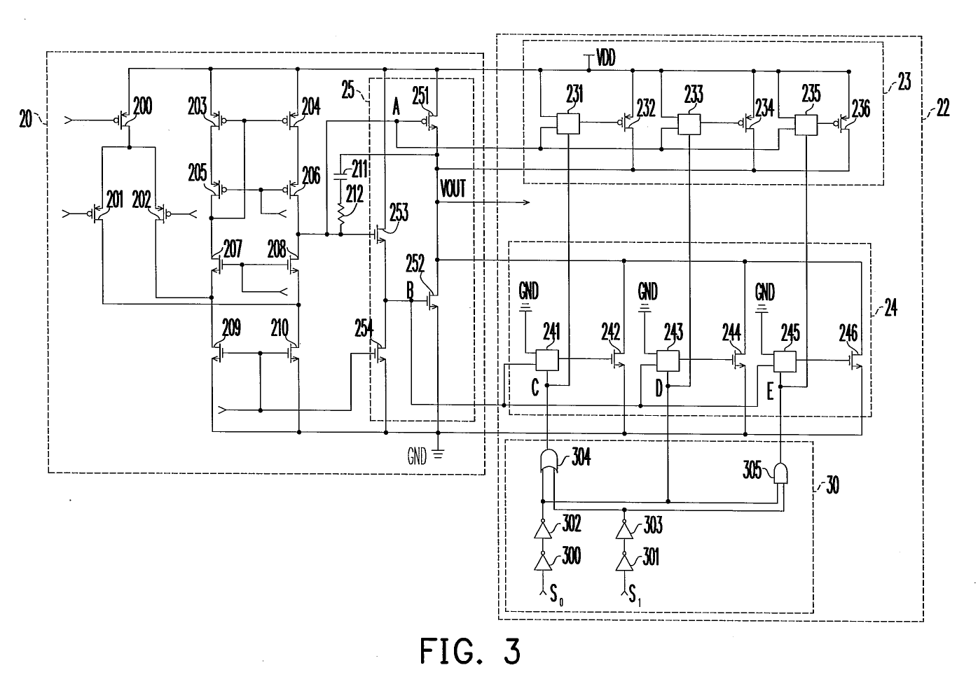

In FIG. 3 another embodiment of the present invention, the current source units 23, 24 are designed according to the circuit architecture of the output stage 25, and use the same working bias to achieve multiple synergistic effect of the driving capability of the output stage 25. FIG. 3 is a circuit diagram of an operational amplifier capable of adjusting the driving capability according to a preferred embodiment of the present invention. Referring to FIG. 3 again, in this embodiment, the operational amplifier 20 includes PMOS transistors 200, 201, 202, 203, 204, 205, 206, NMOS transistors 207, 208, 209, 210, a capacitor 211, a resistor 212, and an output stage 25. The PMOS transistor 201 and the PMOS transistor 202 form a differential input pair. The PMOS transistors 203, 204, 205, 206 and the NMOS transistors 207, 208, 209, 210 form a folded cascade gain stage. The capacitor 211 and the resistor 212 form a compensation network.

The output stage 25 includes a PMOS transistor 251, an NMOS transistor 252, an NMOS transistor 253, and an NMOS transistor 254. The PMOS transistor 251 is coupled between the working voltage VDD and the output terminal VOUT, and a gate terminal of the PMOS transistor 251 is coupled to an “A” terminal bias. The NMOS transistor 252 is coupled between the output terminal VOUT and the ground terminal GND, and a gate terminal of the NMOS transistor 252 is coupled to a “B” terminal bias. The operational amplifier 20 receives and amplifies an analog signal, and outputs a driving current from the output terminal VOUT of the output stage 25. The operational amplifier 20 can be an amplifier of another type, for example, an operational amplifier, a differential amplifier, or the like.

In this embodiment, the driving adjustment circuit 22 includes the current source unit 23, the current source unit 24, and a control unit 30. The current source unit 23 includes a transfer switch 231, a PMOS transistor 232, a transfer switch 233, a PMOS transistor 234, a transfer switch 235, and a PMOS transistor 236. The PMOS transistor 232, the PMOS transistor 234, and the PMOS transistor 236 are coupled between the working voltage VDD and the output terminal. The control terminals of the transfer switch 231, the transfer switch 233, and the transfer switch 235 receive signals from a “C” terminal, a “D” terminal, and an “E” terminal respectively, so as to control the gate terminals of the PMOS transistor 232, the PMOS transistor 234, and the PMOS transistor 236 to be coupled to one of the working voltage VDD or the “A” terminal bias.

The current source unit 24 includes a transfer switch 241, an NMOS transistor 242, a transfer switch 243, an NMOS transistor 244, a transfer switch 245, and an NMOS transistor 246. The NMOS transistor 242, the NMOS transistor 244, and the NMOS transistor 246 are coupled between the output terminal and the ground terminal GND respectively. The control terminals of the transfer switch 241, the transfer switch 243, and the transfer switch 245 receive signals from the C terminal, the D terminal, and the E terminal respectively, so as to control the gate terminals of the NMOS transistor 242, the NMOS transistor 244, and the NMOS transistor 246 to be coupled to one of the ground voltage GND or the B terminal bias.

The control circuit 30 includes inverters 300, 301, 302, 303, or an OR gate 304 and an AND gate 305. Input terminals of the inverter 300 and the inverter 301 are regarded as the input terminal of the control circuit 30, for receiving a control signal S0 and a control signal S1 respectively. Input terminals of the inverter 302 and the inverter 303 are coupled to output terminals of the inverter 300 and the inverter 301 respectively. Two input terminals of the OR gate 304 are coupled to the output terminals of the inverter 302 and the inverter 303 respectively. An output terminal of the OR gate 304 is coupled with the C terminal. The D terminal is coupled with an output terminal of the inverter 302. Two input terminals of the AND gate 305 are coupled to the output terminals of the inverter 302 and the inverter 303 respectively. An output terminal of the OR gate 305 is coupled with the “E” terminal. According to another aspect of the present invention, the “C” terminal, the “D” terminal, and the “E” terminal are three output terminals of the control circuit 30 respectively. Table 1 is given below to describe the input terminals and output terminals of the control circuit more clearly.

TABLE 1
Table of True Values of Input Terminals and Output Terminals of
Control Unit 30

| Input Terminals | | Output Terminals | | |
|---|---|---|---|---|
| Control | | C | | |
| Signal S0 | Control Signal S1 | Terminal | D Terminal | E Terminal |
| 0 | 0 | 0 | 0 | 0 |
| 0 | 1 | 1 | 0 | 0 |
| 1 | 0 | 1 | 1 | 0 |
| 1 | 1 | 1 | 1 | 1 |

Table 1 is a table of true values of inputs and outputs of the control unit 30, in which 0 represents logic 0, i.e., being at a low level, and 1 represents logic 1, i.e., being at a high level. When the “C” terminal is logic 0, the transfer switch 231 switches the gate terminal of the PMOS transistor 232, such that the gate terminal of the PMOS transistor 232 is coupled to the working voltage VDD, and the transfer switch 241 switches the gate terminal of the NMOS transistor 242, such that the gate terminal of the NMOS transistor 242 is coupled to the ground terminal GND. At this time, the PMOS transistor 232 and the NMOS transistor 242 do not work. When the “C” terminal is logic 1, the transfer switch 231 switches the gate terminal of the PMOS transistor 232, such that the gate terminal of the PMOS transistor 232 is coupled to the gate terminal of the PMOS transistor 251, and the transfer switch 241 switches the gate terminal of the NMOS transistor 242, such that the gate terminal of the NMOS transistor 242 is coupled to the gate terminal of the NMOS transistor 252. At this time, a current is generated and flows from the working voltage VDD to the ground terminal GND through the PMOS transistor 232, the output terminal VOUT of the output stage 25, and the NMOS transistor 242 sequentially, so as to adjust the driving current of the output stage 25.

When the D terminal is logic 0, the transfer switch 233 switches the gate terminal of the PMOS transistor 234, such that the gate terminal of the PMOS transistor 234 is coupled to the working voltage VDD, and the transfer switch 243 switches the gate terminal of the NMOS transistor 244, such that the gate terminal of the NMOS transistor 244 is coupled to the ground terminal GND, and the PMOS transistor 234 and the NMOS transistor 244 do not work at this time. When the D terminal is logic 1, the transfer switch 233 switches the gate terminal of the PMOS transistor 234, such that the gate terminal of the PMOS transistor 234 is coupled to the gate terminal of the PMOS transistor 251, and the transfer switch 243 switches the gate terminal of the NMOS transistor 244, such that the gate terminal of the NMOS transistor 244 is coupled to the gate terminal of the NMOS transistor 252. At this time, a current is generated and sequentially flows from the working voltage VDD to the ground terminal GND through the PMOS transistor 234, the output terminal VOUT of the output stage 25, and the NMOS transistor 244, so as to adjust the driving current of the output stage 25.

When the “E” terminal is logic 0, the transfer switch 235 switches the gate terminal of the PMOS transistor 236, such that the gate terminal of the PMOS transistor 236 is coupled to the working voltage VDD, and the transfer switch 245 switches the gate terminal of the NMOS transistor 246, such that the gate terminal of the NMOS transistor 246 is coupled to the ground terminal GND. At this time, the PMOS transistor 236 and the NMOS transistor 246 do not work. When the “E” terminal is logic 1, the transfer switch 235 switches the gate terminal of the PMOS transistor 236, such that the gate terminal of the PMOS transistor 236 is coupled to the gate terminal of the PMOS transistor 251, and the transfer switch 245 switches the gate terminal of the NMOS transistor 246, such that the gate terminal of the NMOS transistor 246 is coupled to the gate terminal of the NMOS transistor 252. At this time, a current is generated and flows from the working voltage VDD to the ground terminal GND through the PMOS transistor 236, the output terminal VOUT of the output stage 25, and the NMOS transistor 246 sequentially, so as to adjust the driving current of the output stage 25.

Referring to Table 1 again, when the control signal S0 and the control signal S1 are both logic 0, the current source unit 23 and the current source unit 24 do not provide the current to the output terminal of the output stage 25. When the control signal S0 and the control signal S1 are “logic 0 and logic 1”, “logic 1 and logic 0”, and “logic 1 and logic 1” respectively, the current source unit 23 and the current source unit 24 provide an increasing current to the output terminal VOUT of the output stage 25, so as to increase the driving current of the output stage 25. Those of ordinary skill in the art can modify the implementation according to the present invention and the teaching of the above embodiments as required. For example, the number of the PMOS transistors in the current source unit 23 is increased or the element design (e.g., the width/length ratio) is modified, the number of the NMOS transistors in the current source unit 24 is increased or the element design (e.g., the width/length ratio) is modified, and the coupling state of the circuit is adjusted appropriately. Thus, the driving current of the output stage 25 can be adjusted, and the details will not be described herein again.

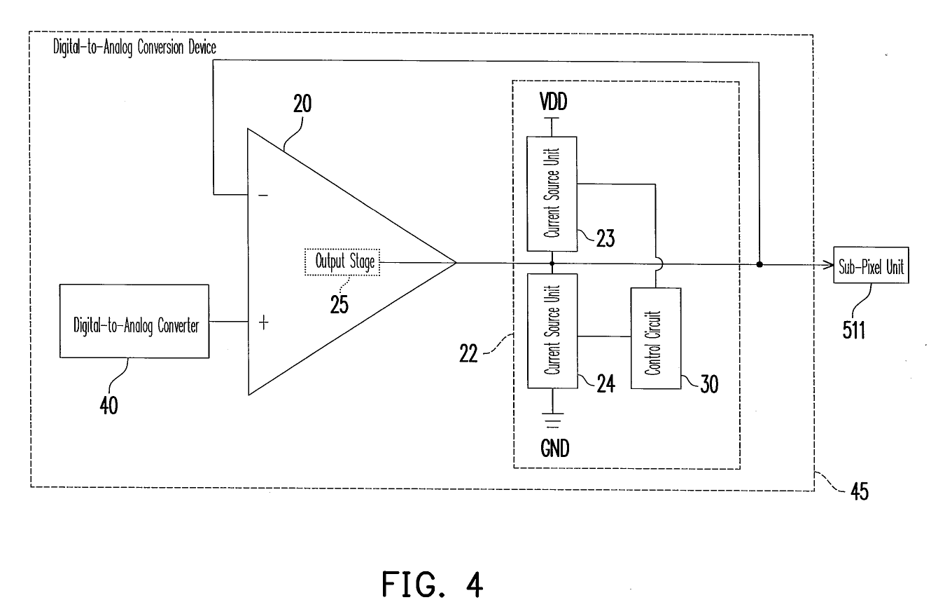

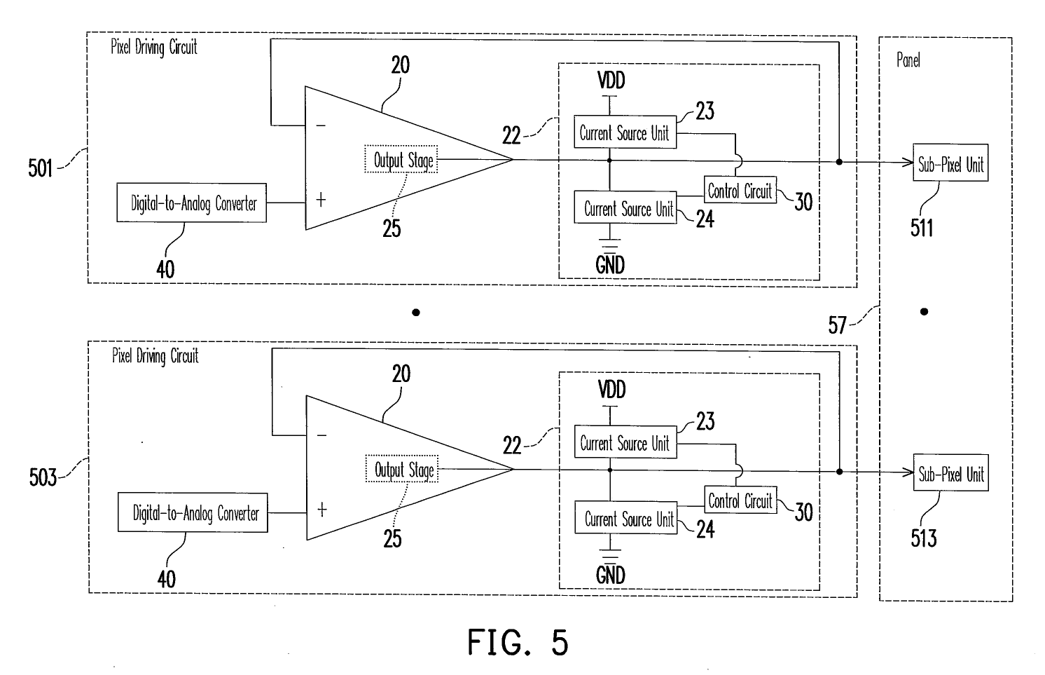

The operational amplifier 20 capable of adjusting the driving capability in the above embodiment is also applicable to a digital-to-analog conversion device. FIG. 4 is a schematic view of a digital-to-analog conversion device according to another embodiment of the present invention. Referring to FIG. 4, in this embodiment, the operational amplifier 20 and the driving adjustment circuit 22 are the same as those of the above embodiment, and the details will not be described herein again. The digital-to-analog conversion device 45 includes a digital-to-analog converter 40, the operational amplifier 20, and the driving adjustment circuit 22. The operational amplifier 20 is coupled between the digital-to-analog converter 40 and a sub-pixel unit 511, and serves as an output buffer of the digital-to-analog converter 40, so as to enhance the driving capability of the digital-to-analog converter 40. In this embodiment, the operational amplifier 20 is an operational amplifier, and forms a unit gain circuit with negative feedback architecture. The driving adjustment circuit 22 is coupled with the operational amplifier 20, so as to adjust the operational amplifier 20 to provide an adequate and appropriate driving current to the sub-pixel unit 511.

Those of ordinary skill in the art can modify the implementation according to the present invention and the teaching of the above embodiments as required. For example, the operational amplifier 20 capable of adjusting the driving capability in the above embodiment can be applied in a display device. FIG. 5 is a schematic view of a display device with an operational amplifier capable of adjusting the driving capability according to a preferred embodiment of the present invention. Referring to FIG. 5, in this embodiment, the display device includes a panel 57 and a plurality of pixel driving circuits 501-503. The panel 57 of this embodiment, for example, is a thin-film transistor liquid crystal display (TFT-LCD) panel. The panel 57 has a plurality of sub-pixel units 511˜513. A plurality of pixel driving circuits 501˜503 is used to sequentially drive the sub-pixel units 511-513. Each of the plurality of pixel driving circuits 501-503 includes the driving adjustment circuit 22, so as to adjust the operational amplifier 20 of the plurality of pixel driving circuits 501˜503, such that an adequate and appropriate current is provided to the plurality of sub-pixel units 511˜513. It should be noted that after the panel 57 is fabricated, the input equivalent capacitance does not always change. Therefore, in application, after the driving capability of the plurality of pixel driving circuits 501˜503 is adjusted, the driving capability of the plurality of pixel driving circuits 501˜503 can be fixed. Thus, the driving capability of the plurality of pixel driving circuits 501˜503 does not need to be adjusted repeatedly.

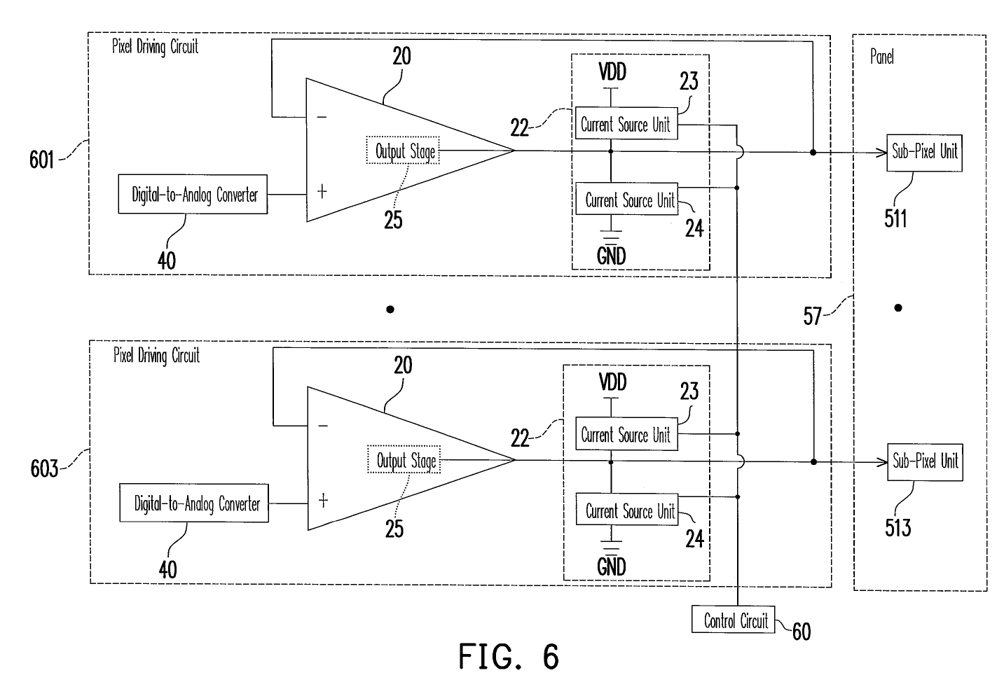

Hereinafter, the technique of adjusting the driving capability of the operational amplifiers 20 will be described with reference to FIG. 6. Referring to FIG. 6, the panel 57 is the same as that of FIG. 5 of the above embodiment. A plurality of pixel driving circuits 601˜603 is similar to that of FIG. 5 of the above embodiment, except that the plurality of pixel driving circuits 601˜603 does not include the control circuits 30. The control circuit 60 controls the driving adjustment circuits 22 in the plurality of pixel driving circuits 601˜603 to output control signals simultaneously, so as to adjust the driving capability of the operational amplifiers 20 in the plurality of pixel driving circuits 601˜603 at one time. Thus, it is unnecessary to arrange a control circuit in each pixel driving circuit, which greatly reduces the cost.

To sum up, the present invention uses a driving adjustment circuit and applications thereof to improve the driving capability of an amplifier by increasing the current of the output stage of the amplifier. The driving adjustment circuit is applicable to different types of output (input) stages. In application, when the driving adjustment circuit is applied in an output stage of a digital-to-analog converter (referring to the amplifier itself or an output stage circuit in the amplifier), the driving capability of the entire digital-to-analog converter can be adjusted according to the load outside the output stage, and the unnecessary power consumption of the output stage can be reduced effectively, so as to improve the stability of the entire digital-to-analog converter.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A system, comprising:
an output stage, having an output terminal; and
a driving adjustment circuit, providing a driving current to the output terminal directly to adjust a driving capability of the output stage.

2. The system as claimed in claim 1, wherein the driving adjustment circuit is a current source circuit.

3. The system as claimed in claim 1, wherein the driving adjustment circuit comprises:
a first current source unit; and
a second current source unit, wherein the first current source unit and the second current source unit are coupled to the output terminal, and the driving capability of the output stage is adjusted according to a magnitude of current conducted by the first current source and the second current source.

4. The system as claimed in claim 1, wherein the output stage is an amplifying circuit.

5. The system as claimed in claim 1, wherein the output stage comprises:
a first transistor, coupled between a working voltage and the output terminal, wherein a control terminal of the first transistor is coupled to a first bias; and
a second transistor, coupled between the output terminal and a ground terminal, wherein a control terminal of the second transistor is coupled to a second bias;
wherein a current of the output terminal is adjusted according to the first bias and the second bias.

6. The system as claimed in claim 3, wherein the first current source unit of the driving adjustment circuit comprises:
a third transistor, coupled between a working voltage and the output terminal;
a first transfer switch, coupled between a control terminal of the third transistor and the first bias;
the second current source unit comprises:
a fourth transistor, coupled between the output terminal and the ground terminal; and
a second transfer switch, coupled between a control terminal of the fourth transistor and the second bias;
wherein the first transfer switch and the second transfer switch selectively conduct the first bias to the control terminal of the third transistor and selectively conduct the second bias to the control terminal of the fourth transistor according to a first control signal.

7. The system as claimed in claim 5, wherein the first transistor is a PMOS transistor, and the second transistor is an NMOS transistor.

8. The system as claimed in claim 6, wherein the third transistor is a PMOS transistor, and the fourth transistor is an NMOS transistor.

9. The system as claimed in claim 1, further comprising a plurality of driving adjustment circuits.

10. The system as claimed in claim 9, further comprising a control circuit for providing a plurality of control signals to control the magnitude of the driving current provided by the driving adjustment circuits.

11. The system as claimed in claim 4, further comprising:
a digital-to-analog converter, receiving a digital signal and converting the digital signal into an analog signal;
a driving adjustment circuit, providing a driving current to the output terminal of the amplifying circuit directly to adjust the driving capability of the amplifying circuit.

12. The system as claimed in claim 11, wherein the amplifying circuit is an operational amplifier, and the operational amplifier further comprises a positive input terminal and a negative input terminal, the positive input terminal is coupled to the analog signal, and the negative input terminal is coupled to the output terminal.

13. The system as claimed in claim 1, further comprising a panel, having a plurality of sub-pixel units, wherein the output stage, for receiving an image signal and outputting the image signal from the output terminal;

14. The system as claimed in claim 13, wherein the panel is a thin-film transistor liquid crystal display panel.
